(19) United States
(12) Patent Application Publication
(10) Pub. No.: US 2026/0052319 A1
(43) Pub. Date: Feb. 19, 2026

(54) SOLID-STATE IMAGING DEVICE

(71) Applicant: Sony Semiconductor Solutions Corporation, Kanagawa (JP)

(72) Inventor: Tomohiro Takahashi, Tokyo (JP)

(21) Appl. No.: 19/101,541

(22) PCT Filed: Aug. 28, 2023
(86) PCT No.: PCT/JP2023/030862

§ 371 Date: Feb. 5, 2025

(30) Foreign Application Priority Data
Sep. 21, 2022 (JP) 2022-150463

(51) Int. Cl. H04N 25/47; H10F 39/00

(52) U.S. Cl. CPC H04N 25/47; H10F 39/8037

(57) ABSTRACT

In one example, a solid-state imaging device includes a pixel array region with pixels for detecting an event. Each of the pixels belonging to any one of first to N-th (N is an integer of 2 or more) groups. First to N-th arbiters are respectively provided for the first to N-th groups of pixels, in which a K-th (K is an integer satisfying 1≤K≤N) arbiter receives request signals output from pixels of a K-th group and outputs a request signal corresponding to any one of the pixels of the K-th group. First to N-th latch units are respectively provided for the first to N-th groups of pixels, in which a K-th latch unit reads a pixel value from a pixel corresponding to the request signal output from the K-th arbiter.

### TECHNICAL FIELD

The present disclosure relates to a solid-state imaging device.

### BACKGROUND ART

An image sensor is a sensor for acquiring an image including a subject, whereas an event sensor (EVS: Event-based Vision Sensor) is a sensor for detecting a change in the subject. The event sensor can set the frame rate higher than that of the image sensor by limiting the sensing target from an “image” to a “change in subject”. The event sensor is realized by, for example, a solid-state imaging device such as a charge coupled device (CCD) sensor or a complementary metal oxide semiconductor (CMOS) sensor, similarly to the image sensor.

### CITATION LIST

### Patent Document

Patent Document 1: Japanese Patent Application Laid-Open No. 2020-136811

### SUMMARY OF THE INVENTION

### Problems to be Solved by the Invention

The EVS of the arbiter type processes the events in the order in which the events are ignited. Therefore, when a plurality of events is ignited at the same time, a waiting time for processing occurs during arbitration of these events.

In this case, an error due to the waiting time occurs between the timing at which the event occurs and the timing at which the time stamp is given to the event. In addition, when the number of events ignited at the same time increases, a processing delay due to the waiting time increases, and the above error increases.

The above error greatly affects the accuracy of information processing in the EVS application, such as causing the shape of the moving subject to be inaccurate.

Therefore, the present disclosure provides a solid-state imaging device capable of quickly processing an event.

### Solutions to Problems

A solid-state imaging device of a first aspect of the present disclosure includes: a pixel array region including a plurality of pixels for detecting an event, each of the plurality of pixels belonging to any one of first to N-th (N is an integer of 2 or more) groups; first to N-th arbiters respectively provided for the first to N-th groups of pixels, in which a K-th (K is an integer satisfying 1≤K≤N) arbiter receives a plurality of request signals output from a plurality of pixels of a K-th group and outputs a request signal corresponding to any one of the plurality of pixels of the K-th group; and first to N-th latch units respectively provided for the first to N-th groups of pixels, in which a K-th latch unit reads a pixel value from a pixel corresponding to the request signal output from the K-th arbiter. As a result, for example, it is possible to process the event quickly, such as reducing the waiting time for the processing due to the arbitration of the event.

Furthermore, in the first aspect, the plurality of pixels in the pixel array region may be arranged in a two-dimensional array along a first direction and a second direction. As a result, for example, it is possible to detect an event by pixels arranged in a two-dimensional array and quickly process the event.

Furthermore, in the first aspect, the pixel array region may include a plurality of signal lines extending in the first direction and separated from each other in the second direction, each of the plurality of signal lines may belong to any one of the first to N-th groups, and the first to N-th group signal lines may respectively transfer request signals output from the first to N-th group pixels to the first to N-th arbiters. As a result, for example, by grouping signal lines similarly to pixels and the like, it is possible to quickly process an event.

Furthermore, in the first aspect, each of the first to N-th groups may include two or more signal lines, and each signal line of the K-th group may be adjacent to a signal line other than the K-th group in the second direction. As a result, for example, it is possible to avoid that pixels of the same group are collectively arranged nearby.

Furthermore, in the first aspect, the pixel array region may include a plurality of read lines extending in the second direction and separated from each other in the first direction, each of the plurality of read lines may belong to any one of the first to N-th groups, and the first to N-th group read lines may respectively transfer pixel values output from the first to N-th group pixels to the first to N-th latch units. As a result, for example, by grouping the read lines similarly to the pixels and the like, it is possible to quickly process the event.

Furthermore, in the first aspect, the first to N-th arbiters may be arranged in the first direction of the pixel array region. As a result, for example, the arbiter can be arranged at a place where the arbiter is easily connected to the signal line.

Furthermore, in the first aspect, the first to N-th arbiters may be arranged in parallel with each other with respect to the pixel array region. As a result, for example, each of the first to N-th arbiters can be arranged in the vicinity of the pixel array region.

Furthermore, in the first aspect, the first to N-th latch units may be arranged in the second direction of the pixel array region. As a result, for example, the latch unit can be arranged at a place where it is easy to be connected to the read line.

Furthermore, in the first aspect, the first to N-th latch units may be respectively arranged in series with the first to N-th arbiters with respect to the pixel array region. As a result, for example, the first to N-th latch units can be made to correspond to the first to N-th arbiters, respectively.

Furthermore, in the first aspect, the K-th latch unit may read the pixel value from a pixel corresponding to the request signal output from the K-th arbiter by outputting an acknowledge signal for the request signal output from the K-th arbiter. As a result, for example, the latch unit can control the operation of the pixel by the acknowledge signal.

Furthermore, the solid-state imaging device of the first aspect may further include first to N-th time stamp units that respectively give time stamps to events detected by the first to N-th group pixels. As a result, for example, it is possible to specify the event by the pixel value not only coordinates but also time.

Furthermore, in the first aspect, the first to N-th time stamp units may operate on the basis of a common clock signal. As a result, for example, the operations of the first to N-th time stamp units can be synchronized.

Furthermore, in the first aspect, the first to N-th time stamp units may be respectively arranged in the first to N-th latch units. As a result, for example, various kinds of information regarding the event including the time stamp can be handled by the latch unit.

Furthermore, in the first aspect, the first to N-th time stamp units may be respectively arranged between the pixel array region and the first to N-th arbiters. As a result, for example, it is possible to handle the time stamp in the vicinity of the pixel array region that is the ignition place of the event.

Furthermore, in the first aspect, the first to N-th time stamp units may respectively give the time stamps with request signals output from the first to N-th group pixels as a trigger. As a result, for example, it is possible to give a time stamp in a short time after the event is ignited.

Furthermore, in the first aspect, the first to N-th arbiters may respectively read the time stamps from the first to N-th time stamp units by using acknowledge signals output from the first to N-th latch units as a trigger. As a result, for example, the time stamp can be read in a short time after the time stamp is given.

Furthermore, in the first aspect, the pixel array region may include a first region and a second region, the first to N-th arbiters may include first to N-th arbiters for the first region and first to N-th arbiters for the second region, and the first to N-th latch units may include first to N-th latch units for the second region and first to N-th latch units for the second region. As a result, for example, the pixel array region can be divided into two regions and managed.

Furthermore, in the first aspect, the first to N-th arbiters may be separated from the pixel array region in a first direction, the first to N-th latch units may be separated from the pixel array region in a second direction, and the first region and the second region may be separated from each other in the first direction. As a result, for example, the pixel array region can be divided by so-called left-right division.

Furthermore, in the first aspect, the pixel array region may include a third region and a fourth region, a part of the first to N-th latch units may be arranged in a vicinity of the third region, and another part of the first to N-th latch units may be arranged in a vicinity of the fourth region. As a result, for example, the pixel array region can be divided into two regions and managed.

Furthermore, in the first aspect, the first to N-th arbiters may be separated from the pixel array region in a first direction, the first to N-th latch units may be separated from the pixel array region in a second direction, and the third region and the fourth region may be separated from each other in the second direction. As a result, for example, the pixel array region can be divided by so-called vertical division.

### BRIEF DESCRIPTION OF DRAWINGS

FIG. 1 is a block diagram illustrating a configuration of a vehicle 1 of a first embodiment.

FIG. 2 is a plan view illustrating a sensing region of the vehicle 1 of the first embodiment.

FIG. 3 is a block diagram illustrating a configuration of a solid-state imaging device of the first embodiment.

FIG. 4 is a block diagram illustrating a configuration of a solid-state imaging device of a comparative example of the first embodiment.

FIG. 5 is a diagram for explaining an operation of the solid-state imaging device of the first embodiment.

FIG. 6 is a graph for comparing the operation of the solid-state imaging device of the first embodiment with the operation of the solid-state imaging device of the comparative example of the first embodiment.

FIG. 7 is a block diagram illustrating a first configuration example of the solid-state imaging device of the first embodiment.

FIG. 8 is a block diagram illustrating a second configuration example of the solid-state imaging device of the first embodiment.

FIG. 9 is a circuit diagram illustrating a configuration example of an arbiter 103a of the first embodiment.

FIG. 10 is a circuit diagram illustrating a first configuration example of a time stamp circuit of the first embodiment.

FIG. 11 is a circuit diagram illustrating a second configuration example of the time stamp circuit of the first embodiment.

FIG. 12 is a block diagram illustrating a configuration of a solid-state imaging device of a second embodiment.

FIG. 13 is a block diagram illustrating a configuration of a solid-state imaging device of a third embodiment.

FIG. 14 is a block diagram illustrating a configuration of a solid-state imaging device of a fourth embodiment.

### MODE FOR CARRYING OUT THE INVENTION

Hereinafter, embodiments of the present disclosure will be described with reference to the drawings.

### First Embodiment

### (1) Vehicle 1 of First Embodiment

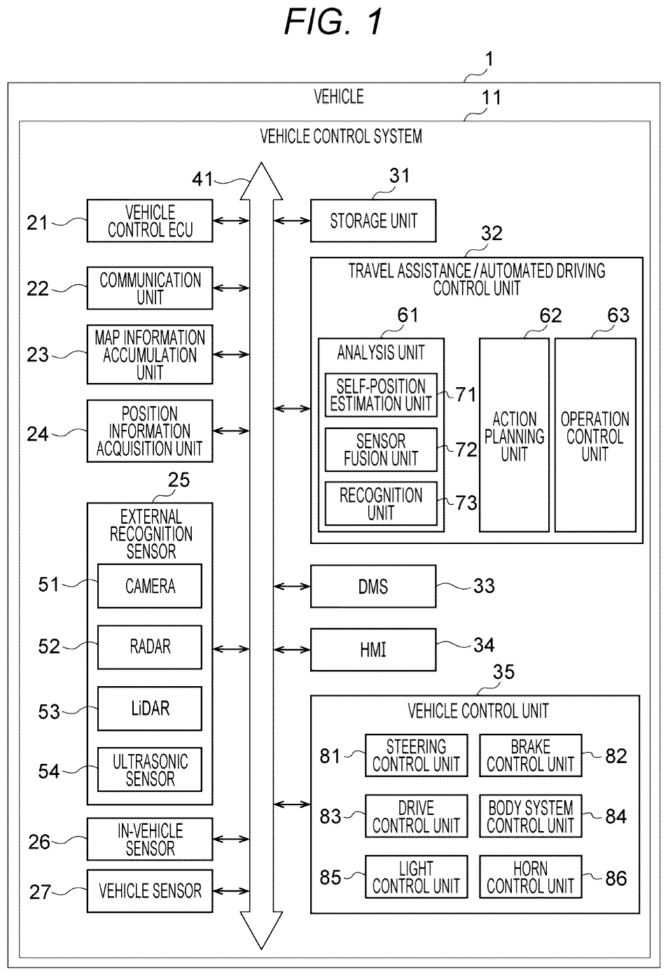

FIG. 1 is a block diagram illustrating a configuration of a vehicle 1 of a first embodiment. FIG. 1 illustrates a configuration example of a vehicle control system 11 which is an example of a mobile device control system.

The vehicle control system 11 is provided in a vehicle 1, and performs processing relating to driver assistance and automated driving of the vehicle 1.

The vehicle control system 11 includes a vehicle control electronic control unit (ECU) 21, a communication unit 22, a map information accumulation unit 23, a position information acquisition unit 24, an external recognition sensor 25, an in-vehicle sensor 26, a vehicle sensor 27, a storage unit 31, a travel assistance/automated driving control unit 32, a driver monitoring system (DMS) 33, a human machine interface (HMI) 34, and a vehicle control unit 35.

The vehicle control ECU 21, the communication unit 22, the map information accumulation unit 23, the position information acquisition unit 24, the external recognition sensor 25, the in-vehicle sensor 26, the vehicle sensor 27, the storage unit 31, the travel assistance/automated driving control unit 32, the driver monitoring system (DMS) 33, the human machine interface (HMI) 34, and the vehicle control unit 35 are communicably connected to each other via a communication network 41. The communication network 41 includes, for example, an in-vehicle communication network, a bus, or the like conforming to a digital bidirectional communication standard such as a controller area network (CAN), a local interconnect network (LIN), a local area network (LAN), FlexRay (registered trademark), or Ethernet (registered trademark). The communication network 41 may be selectively used in a manner that depends on the type of data to be transmitted. For example, the CAN may be applied to data related to vehicle control, and the Ethernet may be applied to large-volume data. Note that each component of the vehicle control system 11 may be directly connected using wireless communication adapted to a relatively short-range communication, such as near field communication (NFC) or Bluetooth (registered trademark), without using the communication network 41, for example.

Note that, hereinafter, in a case where each component of the vehicle control system 11 performs communication via the communication network 41, the description of the communication network 41 will be omitted. For example, a case where the vehicle control ECU 21 and the communication unit 22 perform communication via the communication network 41 will be simply described as the vehicle control ECU 21 and the communication unit 22 performing communication.

### [Vehicle Control Ecu 21]

For example, the vehicle control ECU 21 includes various processors such as a central processing unit (CPU) and a micro processing unit (MPU). The vehicle control ECU 21 controls all or some of the functions of the vehicle control system 11.

### [Communication Unit 22]

The communication unit 22 communicates with various devices inside and outside the vehicle, other vehicles, servers, base stations, and the like, and transmits and receives various types of data. In doing so, the communication unit 22 can perform communication using a plurality of communication methods.

Communication with the outside of the vehicle executable by the communication unit 22 will be schematically described. The communication unit 22 communicates with a server (hereinafter referred to as external server) or the like present on an external network via a base station or an access point using a wireless communication method such as fifth generation mobile communication system (5G), long term evolution (LTE), dedicated short range communications (DSRC), or the like, for example. Examples of the external network over which the communication unit 22 performs communication include the Internet, a cloud network, a proprietary network, and the like. A communication method by which the communication unit 22 performs communication over the external network is not particularly limited as long as the method is a wireless communication method that allows digital bidirectional communication at a communication speed equal to or higher than a predetermined speed and over a distance equal to or longer than a predetermined distance.

Furthermore, the communication unit 22 can communicate with a terminal present in the vicinity of the host vehicle, using a peer to peer (P2P) technology, for example. The terminal present in the vicinity of the host vehicle is a terminal attached to a mobile object moving at a relatively low speed such as a pedestrian or a bicycle, a terminal stationarily installed in a store or the like, or a machine type communication (MTC) terminal, for example. Moreover, the communication unit 22 can also perform V2X communication. The V2X communication refers to communication between the host vehicle and another vehicle, such as vehicle to vehicle communication with another vehicle, vehicle to infrastructure communication with a roadside device or the like, vehicle to home communication, and vehicle to pedestrian communication with a terminal or the like carried by a pedestrian, for example.

The communication unit 22 can receive a program for updating software that controls the operation of the vehicle control system 11 from the outside (Over The Air), for example. The communication unit 22 can further receive map information, traffic information, information regarding the surroundings of the vehicle 1, and the like from the outside. Furthermore, the communication unit 22 can transmit information regarding the vehicle 1, information regarding the surroundings of the vehicle 1, and the like to the outside, for example. Examples of the information regarding the vehicle 1 transmitted to the outside by the communication unit 22 include data indicating a state of the vehicle 1, a recognition result from a recognition unit 73, and the like. Moreover, the communication unit 22 performs communication compatible with a vehicle emergency call system such as eCall, for example.

For example, the communication unit 22 receives an electromagnetic wave transmitted by Vehicle Information and Communication System (VICS) (registered trademark), such as a radio beacon, an optical beacon, or FM multiplex broadcasting.

Communication with the inside of the vehicle executable by the communication unit 22 will be schematically described. The communication unit 22 can communicate with each device in the vehicle using wireless communication, for example. The communication unit 22 can perform wireless communication with a device in the vehicle using a wireless communication method that allows digital bidirectional communication at a communication speed equal to or higher than a predetermined speed, such as wireless LAN, Bluetooth, NFC, or wireless universal serial bus (WUSB), for example. The present invention is not limited thereto, and the communication unit 22 can also communicate with each device in the vehicle using wired communication. For example, the communication unit 22 can communicate with each device in the vehicle using wired communication via a cable connected to a connecting terminal not illustrated in the drawing. The communication unit 22 can communicate with each device in the vehicle using a wired communication method that allows digital bidirectional communication at a communication speed equal to or higher than a predetermined speed, such as universal serial bus (USB), high-definition multimedia interface (HDMI) (registered trademark), or mobile high-definition link (MHL), for example.

Here, the device in the vehicle refers to, for example, a device that is not connected to the communication network 41 in the vehicle. Possible examples of the device in the vehicle include a mobile device and a wearable device carried by an occupant such as a driver, an information device brought into the vehicle and temporarily installed, and the like.

### [Map Information Accumulation Unit 23]

The map information accumulation unit 23 accumulates either or both of a map acquired from the outside and a map created by the vehicle 1. For example, the map information accumulation unit 23 accumulates a three-dimensional high-precision map, a global map that is lower in precision but wider in covering area than the high-precision map, and the like.

Examples of the high-precision map include a dynamic map, a point cloud map, a vector map, and the like. The dynamic map is a map including four layers: dynamic information, semi-dynamic information, semi-static information, and static information, and is provided to the vehicle 1 from the external server or the like, for example. The point cloud map is a map including a point cloud (point cloud data). The vector map is, for example, a map adapted to an advanced driver assistance system (ADAS) or autonomous driving (AD), the map being obtained by associating traffic information such as lane positions and traffic light positions with a point cloud map.

The point cloud map and the vector map may be provided from, for example, the external server or the like, or may be created by the vehicle 1 as a map for matching with a local map to be described later on the basis of a sensing result from a camera 51, a radar 52, a LiDAR 53, or the like, and may be accumulated in the map information accumulation unit 23. Alternatively, in a case where the high-precision map is provided from the external server or the like, to reduce the communication volume, map data of several hundred meters square regarding a planned route that the vehicle 1 will follow is acquired from the external server or the like, for example.

### [Position Information Acquisition Unit 24]

The position information acquisition unit 24 receives a global navigation satellite system (GNSS) signal from a GNSS satellite, and acquires position information of the vehicle 1. The acquired position information is supplied to the travel assistance/automated driving control unit 32. Note that the position information acquisition unit 24 is not limited to a method using a GNSS signal and may acquire the position information using a beacon, for example.

### [External Recognition Sensor 25]

The external recognition sensor 25 includes various sensors that are used to recognize conditions outside the vehicle 1, and supplies sensor data from each sensor to each component of the vehicle control system 11. The type and number of the sensors included in the external recognition sensor 25 are determined as desired.

For example, the external recognition sensor 25 includes the camera 51, the radar 52, the light detection and ranging or laser imaging detection and ranging (LiDAR) 53, and an ultrasonic sensor 54. The present invention is not limited thereto, and the external recognition sensor 25 is only required to include at least one of the camera 51, the radar 52, the LiDAR 53, or the ultrasonic sensor 54. The numbers of cameras 51, radars 52, LiDARs 53, and ultrasonic sensors 54 are not particularly limited as long as the numbers are practically feasible to be installed in the vehicle 1. Furthermore, the types of sensors included in the external recognition sensor 25 are not limited to this example, and the external recognition sensor 25 may include a sensor of some other type. An example of the sensing region of each sensor included in the external recognition sensor 25 will be described later.

Note that the imaging method of the camera 51 is not particularly limited. For example, cameras adapted to various imaging methods that allow distance measurement, such as a time of flight (ToF) camera, a stereo camera, a monocular camera, and an infrared camera, can be used as the camera 51, as necessary. The present invention is not limited thereto, and the camera 51 may be a camera for simply acquiring a captured image without distance measurement.

Furthermore, for example, the external recognition sensor 25 can include an environment sensor for detecting the environment around the vehicle 1. The environment sensor is a sensor for detecting an environment such as weather, climate, and brightness, and can include, for example, various sensors such as a raindrop sensor, a fog sensor, a sunshine sensor, a snow sensor, and an illuminance sensor.

Moreover, for example, the external recognition sensor 25 includes a microphone used for detecting sound around the vehicle 1, a position of a sound source, and the like.

### [In-Vehicle Sensor 26]

The in-vehicle sensor 26 includes various sensors for detecting information regarding the inside of the vehicle, and supplies sensor data from each sensor to each component of the vehicle control system 11. The type and number of the various sensors included in the in-vehicle sensor 26 are not particularly limited as long as the type and number are practically feasible to be installed in the vehicle 1.

For example, the in-vehicle sensor 26 can include one or more types of sensors among a camera, a radar, a seating sensor, a steering wheel sensor, a microphone, and a biometric sensor. As the camera included in the in-vehicle sensor 26, for example, cameras adapted to various imaging methods that allow distance measurement, such as a ToF camera, a stereo camera, a monocular camera, and an infrared camera, can be used. The present invention is not limited thereto, and the camera included in the in-vehicle sensor 26 may be a camera for simply acquiring a captured image without distance measurement. The biometric sensor included in the in-vehicle sensor 26 is disposed on a seat, a steering wheel, or the like, for example, and detects various types of biometric information regarding an occupant such as a driver.

### [Vehicle Sensor 27]

The vehicle sensor 27 includes various sensors for detecting the state of the vehicle 1, and supplies sensor data from each sensor to each component of the vehicle control system 11. The type and number of the various sensors included in the vehicle sensor 27 are not particularly limited as long as the type and number are practically feasible to be installed in the vehicle 1.

For example, the vehicle sensor 27 includes a speed sensor, an acceleration sensor, an angular velocity sensor (gyroscope), and an inertial measurement unit (IMU) obtained by integrating these sensors. For example, the vehicle sensor 27 includes a steering angle sensor that detects a steering angle of the steering wheel, a yaw rate sensor, an accelerator sensor that detects an operation amount of an accelerator pedal, and a brake sensor that detects an operation amount of a brake pedal. For example, the vehicle sensor 27 includes a rotation sensor that detects an engine speed or a motor speed, a pneumatic sensor that detects a tire pressure, a slip rate sensor that detects a tire slip rate, and a wheel speed sensor that detects a wheel speed. For example, the vehicle sensor 27 includes a battery sensor that detects a remaining battery level and a battery temperature, and an impact sensor that detects external impact.

### [Storage Unit 31]

The storage unit 31 includes at least one of a nonvolatile storage medium or a volatile storage medium, and stores data and a program. The storage unit 31 is used as, for example, an electrically erasable programmable read-only memory (EEPROM) and a random access memory (RAM), and a magnetic storage device such as a hard disc drive (HDD), a semiconductor storage device, an optical storage device, and a magneto-optical storage device can be applied as the storage medium. The storage unit 31 stores various programs and data used by each unit of the vehicle control system 11. For example, the storage unit 31 includes an event data recorder (EDR) and a data storage system for automated driving (DSSAD), and stores information regarding the vehicle 1 before and after an event such as an accident and information acquired by the in-vehicle sensor 26.

### [Travel Assistance/Automated Driving Control Unit 32]

The travel assistance/automated driving control unit 32 controls travel support and automated driving of the vehicle 1. For example, the travel assistance/automated driving control unit 32 includes an analysis unit 61, an action planning unit 62, and an operation control unit 63.

The analysis unit 61 performs analysis processing on the vehicle 1 and conditions around the vehicle 1. The analysis unit 61 includes a self-position estimation unit 71, a sensor fusion unit 72, and the recognition unit 73.

The self-position estimation unit 71 estimates the self-position of the vehicle 1 on the basis of sensor data from the external recognition sensor 25 and the high-precision map accumulated in the map information accumulation unit 23. For example, the self-position estimation unit 71 generates a local map on the basis of sensor data from the external recognition sensor 25, and performs matching between the local map and the high-precision map to estimate the self-position of the vehicle 1. The position of the vehicle 1 is based on, for example, the center of a rear wheel pair axle.

Examples of the local map include a three-dimensional high-precision map created by using a technology such as simultaneous localization and mapping (SLAM), an occupancy grid map, and the like. The three-dimensional high-precision map is the above-described point cloud map or the like, for example. The occupancy grid map is a map in which a three-dimensional or two-dimensional space around the vehicle 1 is divided into grids of a predetermined size, and an occupancy state of an object is indicated in units of grids. The occupancy state of the object is indicated by the presence or absence, or existence probability of the object, for example. The local map is also used in detection processing and recognition processing performed on the conditions outside the vehicle 1 by the recognition unit 73, for example.

Note that the self-position estimation unit 71 may estimate the self-position of the vehicle 1 on the basis of the position information acquired by the position information acquisition unit 24 and the sensor data from the vehicle sensor 27.

The sensor fusion unit 72 performs sensor fusion processing of combining a plurality of different types of sensor data (for example, image data supplied from the camera 51 and sensor data supplied from the radar 52), to acquire new information. Methods for combining different types of sensor data include integration, fusion, association, and the like.

The recognition unit 73 performs the detection processing on the conditions outside the vehicle 1 and the recognition processing on the conditions outside the vehicle 1.

For example, the recognition unit 73 performs the detection processing and recognition processing on the conditions outside the vehicle 1 on the basis of information from the external recognition sensor 25, information from the self-position estimation unit 71, information from the sensor fusion unit 72, and the like.

Specifically, for example, the recognition unit 73 performs detection processing, recognition processing, and the like on an object around the vehicle 1. The object detection processing is, for example, processing of detecting the presence or absence, size, shape, position, motion, and the like of an object. The object recognition processing is, for example, processing of recognizing an attribute such as a type of an object or identifying a specific object. The detection processing and the recognition processing, however, are not necessarily clearly separated and may overlap.

For example, the recognition unit 73 detects an object around the vehicle 1 by performing clustering to classify point clouds based on sensor data from the radar 52, the LiDAR 53, or the like into clusters of point clouds. This allows for the detection of the presence or absence, size, shape, and position of the object around the vehicle 1.

For example, the recognition unit 73 detects the motion of the object around the vehicle 1 by performing tracking to follow the motion of the cluster of point clouds classified by clustering. This allows for the detection of the speed and traveling direction (movement vector) of the object around the vehicle 1.

For example, the recognition unit 73 detects or recognizes a vehicle, a person, a bicycle, an obstacle, a structure, a road, a traffic light, a traffic sign, a road sign, and the like, on the basis of image data supplied from the camera 51. Furthermore, the recognition unit 73 may recognize the type of the object around the vehicle 1 by performing recognition processing such as semantic segmentation.

For example, the recognition unit 73 can perform recognition processing on traffic rules around the vehicle 1 on the basis of the map accumulated in the map information accumulation unit 23, the result of estimating the self-position from the self-position estimation unit 71, and the result of recognizing the object around the vehicle 1 from the recognition unit 73. Through this processing, the recognition unit 73 can recognize the positions and states of traffic lights, the details of traffic signs and road signs, the details of traffic regulations, drivable lanes, and the like.

For example, the recognition unit 73 can perform recognition processing on a surrounding environment of the vehicle 1. Possible examples of the surrounding environment to be recognized by the recognition unit 73 include weather, air temperature, humidity, brightness, road surface conditions, and the like.

The action planning unit 62 creates an action plan of the vehicle 1. For example, the action planning unit 62 creates the action plan by performing path planning and path following processing.

Note that the path planning (global path planning) is processing of planning a rough path from a start to a goal. This path planning also includes processing called trajectory planning in which trajectory generation (local path planning) is performed, the local path planning enabling safe and smooth advancing in the vicinity of the vehicle 1 in consideration of the motion characteristics of the vehicle 1 in the planned path.

The path following is processing of planning operations for safe and accurate travelling along the path planned by the path planning within a planned time. For example, the action planning unit 62 can calculate a target speed and a target angular velocity of the vehicle 1, on the basis of the result of the path following processing.

The operation control unit 63 controls operations of the vehicle 1 to achieve the action plan created by the action planning unit 62.

For example, the operation control unit 63 controls the steering control unit 81, the brake control unit 82, and the drive control unit 83 included in the vehicle control unit 35 to be described later, and performs acceleration/deceleration control and direction control such that the vehicle 1 travels on the trajectory calculated by the trajectory plan. For example, the operation control unit 63 performs coordinated control to achieve ADAS functions such as collision avoidance or mitigation, follow driving, speed maintenance driving, collision warning for the host vehicle, lane departure warning for the host vehicle, and the like. For example, the operation control unit 63 performs coordinated control to achieve automated driving or the like in which a vehicle autonomously travels without depending on the operation by the driver.

### [DMS33]

The DMS 33 performs authentication processing of the driver, recognition processing of the state of the driver, and the like on the basis of sensor data from the in-vehicle sensor 26, input data input to the HMI 34 to be described later, and the like. Possible examples of the state of the driver to be recognized include a physical condition, an alertness level, a concentration level, a fatigue level, a line-of-sight direction, a drunkenness level, a driving operation, a posture, and the like.

Note that the DMS 33 may perform authentication processing of a passenger other than the driver and recognition processing of the state of the passenger. Furthermore, for example, the DMS 33 may perform recognition processing of the situation inside the vehicle on the basis of sensor data from the in-vehicle sensor 26. Possible examples of the conditions inside the vehicle to be recognized include temperature, humidity, brightness, odor, and the like.

### [HMI34]

The HMI 34 inputs various data, instructions, and the like, and presents various data to the driver and the like.

Data input by the HMI 34 will be schematically described. The HMI 34 includes an input device for a person to input data. The HMI 34 generates an input signal on the basis of data, an instruction, or the like input by an input device, and supplies the input signal to each unit of the vehicle control system 11. The HMI 34 includes an operator such as a touch panel, a button, a switch, and a lever as an input device. The present invention is not limited thereto, and the HMI 34 may further include an input device capable of inputting information by a method other than manual operation by voice, gesture, or the like. Furthermore, the HMI 34 may use, for example, a remote control device using infrared rays or radio waves, or an external connection device such as a mobile device or a wearable device corresponding to the operation of the vehicle control system 11 as an input device.

Presentation of data by the HMI 34 will be schematically described. The HMI 34 generates visual information, auditory information, and tactile information for the passenger or the outside of the vehicle. In addition, the HMI 34 performs output control for controlling output, output content, output timing, output method, and the like of each piece of generated information. The HMI 34 generates and outputs, for example, an operation screen, a state display of the vehicle 1, a warning display, an image such as a monitor image indicating a situation around the vehicle 1, and information indicated by light as the visual information. Further, the HMI 34 generates and outputs information indicated by sounds such as voice guidance, a warning sound, and a warning message, for example, as the auditory information. Further, the HMI 34 generates and outputs, as the tactile information, information given to the tactile sense of the passenger by, for example, force, vibration, motion, or the like.

As an output device that the HMI 34 outputs visual information, for example, a display device that presents visual information by displaying an image by itself or a projector device that presents visual information by projecting an image can be applied. Note that the display device may be a device that displays the visual information in the field of view of the occupant, such as a head-up display, a transmissive display, or a wearable device having an augmented reality (AR) function, for example, in addition to a display device having a normal display. In the HMI 34, a display device included in a navigation device, an instrument panel, a camera monitoring system (CMS), an electronic mirror, a lamp, or the like provided in the vehicle 1 can also be used as an output device that outputs visual information.

As an output device from which the HMI 34 outputs the auditory information, for example, an audio speaker, a headphone, or an earphone can be applied.

As an output device to which the HMI 34 outputs tactile information, for example, a haptic element using a haptic technology can be applied. The haptic element is provided, for example, at a portion to be touched by the occupant of the vehicle 1, such as the steering wheel or the seat.

### [Vehicle Control Unit 35]

The vehicle control unit 35 controls each unit of the vehicle 1. The vehicle control unit 35 includes a steering control unit 81, a brake control unit 82, a drive control unit 83, a body system control unit 84, a light control unit 85, and a horn control unit 86.

The steering control unit 81 performs detection, control, and the like of the state of a steering system of the vehicle 1. The steering system includes, for example, a steering mechanism including a steering wheel and the like, an electric power steering, and the like. The steering control unit 81 includes, for example, a steering ECU that controls the steering system, an actuator that drives the steering system, and the like.

The brake control unit 82 performs detection, control, and the like of the state of a brake system of the vehicle 1. The brake system includes, for example, a brake mechanism including a brake pedal and the like, an antilock brake system (ABS), a regenerative brake mechanism, and the like. The brake control unit 82 includes, for example, a brake ECU that controls the brake system, an actuator that drives the brake system, and the like.

The drive control unit 83 performs detection, control, and the like of the state of a drive system of the vehicle 1. The drive system includes, for example, an accelerator pedal, a driving force generation device for generating a driving force such as an internal combustion engine or a driving motor, a driving force transmission mechanism for transmitting the driving force to wheels, and the like. The drive control unit 83 includes, for example, a drive ECU that controls the drive system, an actuator that drives the drive system, and the like.

The body system control unit 84 performs detection, control, and the like of the state of a body system of the vehicle 1. The body system includes, for example, a keyless entry system, a smart key system, a power window device, a power seat, an air conditioner, an airbag, a seat belt, a shift lever, and the like. The body system control unit 84 includes, for example, a body system ECU that controls the body system, an actuator that drives the body system, and the like.

The light control unit 85 performs detection, control, and the like of the states of various lights of the vehicle 1. Possible examples of the lights to be controlled include a headlight, a backlight, a fog light, a turn signal, a brake light, a projection light, a bumper indicator, and the like. The light control unit 85 includes a light ECU that controls the lights, an actuator that drives the lights, and the like.

The horn control unit 86 performs detection, control, and the like of the state of a car horn of the vehicle 1. The horn control unit 86 includes, for example, a horn ECU that controls the car horn, an actuator that drives the car horn, and the like.

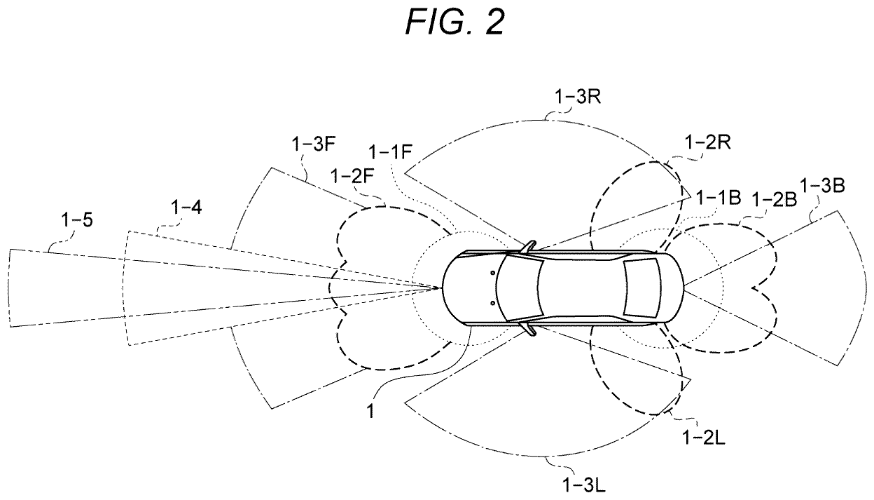

FIG. 2 is a plan view illustrating a sensing region of the vehicle 1 according to the first embodiment. FIG. 2 illustrates an example of a sensing region by the camera 51, the radar 52, the LiDAR 53, the ultrasonic sensor 54, and the like of the external recognition sensor 25 in FIG. 1. Note that FIG. 2 schematically illustrates the vehicle 1 as viewed from above, where a left end side is the front end (front) side of the vehicle 1 and a right end side is the rear end (rear) side of the vehicle 1.

### [Sensing Region 1-1F, B]

A sensing region 1-1F and a sensing region 1-1B illustrate examples of the sensing region of the ultrasonic sensor 54. The sensing region 1-1F covers the periphery of the front end of the vehicle 1 by the plurality of ultrasonic sensors 54. The sensing region 1-1B covers the periphery of the rear end of the vehicle 1 by the plurality of ultrasonic sensors 54.

The sensing results in the sensing region 1-1F and the sensing region 1-1B are used, for example, for parking assistance of the vehicle 1.

### [Sensing Regions 1-2F, B, L, and R]

Sensing regions 1-2F to 1-2B illustrate examples of sensing regions of the radar 52 for a short distance or a middle distance. The sensing region 1-2F covers a position farther than the sensing region 1-1F in front of the vehicle 1. The sensing region 1-2B covers a position farther than the sensing region 1-1B behind the vehicle 1. The sensing region 1-2L covers the rear periphery of the left side surface of the vehicle 1. The sensing region 1-2R covers the rear periphery of the right side surface of the vehicle 1.

The sensing result in the sensing region 1-2F is used, for example, to detect a vehicle, a pedestrian, or the like existing in front of the vehicle 1. The sensing result in the sensing region 1-2B is used, for example, for a collision prevention function or the like behind the vehicle 1. The sensing results in the sensing region 1-2L and the sensing region 1-2R are used, for example, for detecting an object in a blind spot on the side of the vehicle 1.

### [Sensing Regions 1-3F, B, L, and R]

Sensing regions 1-3F to 1-3B illustrate examples of sensing regions by the camera 51. The sensing region 1-3F covers a position farther than the sensing region 1-2F in front of the vehicle 1. The sensing region 1-3B covers a position farther than the sensing region 1-2B behind the vehicle 1. The sensing region 1-3L covers the periphery of the left side surface of the vehicle 1. The sensing region 1-3R covers the periphery of the right side surface of the vehicle 1.

The sensing result in the sensing region 1-3F can be used for, for example, recognition of a traffic light or a traffic sign, a lane departure prevention assist system, and an automatic headlight control system. The sensing result in the sensing region 1-3B can be used for, for example, parking assistance and a surround view system. The sensing results in the sensing region 1-3L and the sensing region 1-3R can be used, for example, in a surround view system.

### [Sensing Region 1-4]

A sensing region 1-4 illustrates an example of a sensing region of the LiDAR 53. The sensing region 1-4 covers a position farther than the sensing region 1-3F in front of the vehicle 1. On the other hand, the sensing region 1-4 has a narrower range in the left-right direction than the sensing region 1-3F.

The sensing result in the sensing region 1-4 is used, for example, for detecting an object such as a surrounding vehicle.

### [Sensing Region 1-5]

A sensing region 1-5 is an example of a sensing region of the radar 52 for a long distance. The sensing region 1-5 covers a position farther than the sensing region 1-4 in front of the vehicle 1. On the other hand, the sensing region 1-5 has a narrower range in the left-right direction than the sensing region 1-4.

The sensing result in the sensing region 1-5 is used for, for example, adaptive cruise control (ACC), emergency braking, collision avoidance, and the like.

Note that the sensing regions of the respective sensors of the camera 51, the radar 52, the LiDAR 53, and the ultrasonic sensor 54 included in the external recognition sensor 25 may have various configurations other than those in FIG. 2. Specifically, the ultrasonic sensor 54 may also perform sensing on the sides of the vehicle 1, or the LiDAR 53 may perform sensing on the rear side of the vehicle 1. Furthermore, the installation position of each sensor is not limited to the above-described example. Furthermore, the number of each sensor may be one or more.

### (2) Solid-State Imaging Device of First Embodiment

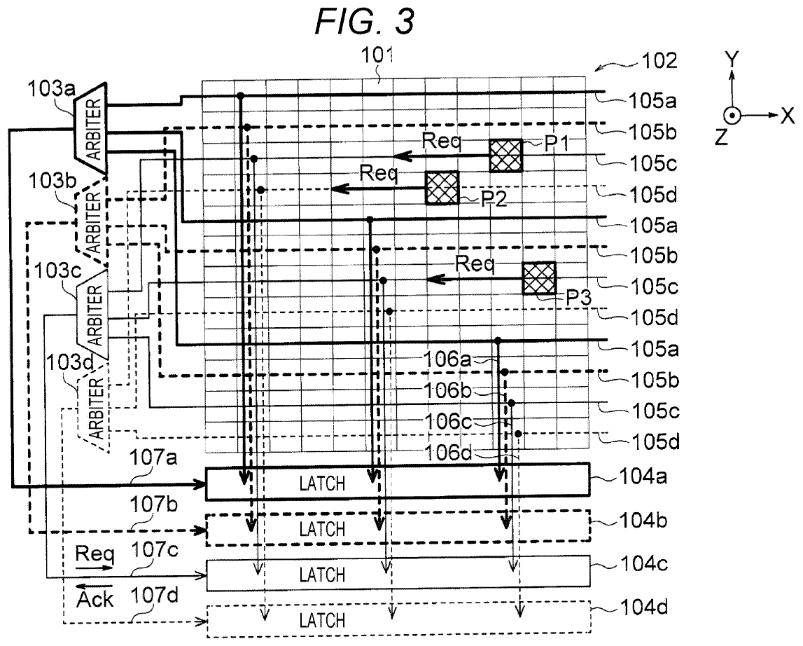

FIG. 3 is a block diagram illustrating a configuration of a solid-state imaging device of the first embodiment.

The solid-state imaging device of the present embodiment is provided in the vehicle 1 illustrated in FIG. 1, and is included in, for example, the external recognition sensor 25. The solid-state imaging device of the present embodiment is an EVS for detecting a change in a subject. Examples of the subject of the present embodiment include a person, a vehicle, an obstacle, and the like existing in front of the vehicle 1.

As illustrated in FIG. 3, the solid-state imaging device of the present embodiment includes a pixel array region 102 including a plurality of pixels 101, a plurality of arbiters 103a to 103d, a plurality of latch units 104a to 104d, a plurality of signal lines 105a to 105d, a plurality of read lines 106a to 106d, and a plurality of signal lines 107a to 107d. Each of the arbiters 103a to 103d is also appropriately referred to as “arbiter 103”, and each of the latch units 104a to 104d is also appropriately referred to as “latch unit 104”. Similarly, the signal lines 105a to 105d, the read lines 106a to 106d, and the signal lines 107a to 107d are also appropriately referred to as “signal line 105”, “read line 106”, and “signal line 107”, respectively.

FIG. 3 illustrates an X axis, a Y axis, and a Z axis perpendicular to each other. The X direction and the Y direction correspond to the lateral direction, and the Z direction corresponds to the longitudinal direction. In addition, the +Z direction corresponds to an upward direction, and the −Z direction corresponds to a downward direction. Note that the −Z direction may strictly match the gravity direction, or does not necessarily strictly match the gravity direction. The ±X direction is an example of a first direction of the present disclosure, and the ±Y direction is an example of a second direction of the present disclosure.

### [Pixel 101, Pixel Array Region 102]

The plurality of pixels 101 described above is arranged in a two-dimensional array along the X direction and the Y direction in the pixel array region 102. Although FIG. 3 illustrates 144 (=12×12) pixels 101, the number of pixels 101 in the pixel array region 102 may be another number. The X direction corresponds to the row direction (horizontal direction) of the pixel array region 102, and the Y direction corresponds to the column direction (vertical direction) of the pixel array region 102.

Each pixel 101 of the present embodiment has a function of detecting an event such as an on-event or an off-event. The on-event is ignited in a case where the absolute value of the change amount (increase amount) of the luminance is larger than the threshold in a case where the luminance of the pixel 101 increases. The off-event is ignited in a case where the absolute value of the change amount (decrease amount) of the luminance is larger than the threshold in the case where the luminance of the pixel 101 decreases. For example, the on-event is ignited when the subject enters the pixel 101, and the off-event is ignited when the subject leaves the pixel 101.

### [Signal Line 105]

The signal lines 105a to 105d are arranged over the inside and the outside of the pixel array region 102, and are electrically connected to the arbiters 103a to 103d, respectively. In the pixel array region 102, the signal lines 105a to 105d extend in the X direction and are separated from each other in the Y direction. In FIG. 3, in order to distinguish the signal lines 105a to 105d from each other, the signal lines 105a, 105b, 105c, and 105d are illustrated by “thick solid line”, “thick broken line”, “thin solid line”, and “thin broken line”, respectively (the similarity applies hereinafter).

Each of the signal lines 105a to 105d is arranged at a position overlapping the 12 pixels 101 for one row in the Z direction, and is electrically connected to these pixels 101. For example, in FIG. 3, one signal line 105a arranged at the end in the +Y direction of the pixel array region 102 is electrically connected to 12 pixels 101 for one row arranged at the end in the +Y direction of the pixel array region 102. The signal line 105a may be arranged in the +Z direction of these pixels 101 or may be arranged in the −Z direction of these pixels 101. The similarity applies to the other signal lines 105a to 105d. The solid-state imaging device of the present embodiment includes 12 signal lines 105a to 105d corresponding to 144 pixels 101 for 12 rows, and specifically includes three signal lines 105a, three signal lines 105b, three signal lines 105c, and three signal lines 105d.

The signal lines 105a to 105d belong to groups a to d, respectively. Similarly, the pixels 101 electrically connected to the signal lines 105a to 105d also belong to the groups a to d, respectively. The pixels 101 belonging to the groups a to d are electrically connected to the arbiters 103a to 103d via the signal lines 105a to 105d, respectively. For example, in FIG. 3, one signal line 105a arranged at the end in the +Y direction of the pixel array region 102 and the pixels 101 of one row belong to the group a and are electrically connected to the arbiter 103a. The similarity applies to the other signal lines 105a to 105d and the pixels 101. The groups a to d are examples of first to N-th (N is an integer of 2 or more) groups of the present disclosure. The value of N is 4 in the present embodiment, but may be another value. Each of the groups a to d is an example of a K-th (K is an integer satisfying 1≤K≤N) group of the present disclosure.

When an event is ignited in a certain pixel 101, a Req (request) signal is output from the pixel 101. The Req signal is output to the signal line 105 electrically connected to the pixel 101. Therefore, the Req signal output from the pixel 101 of a certain group is transferred to the arbiter 103 of the group via the signal line 105 of the group. The Req signal output from each pixel 101 is a signal requesting resetting of the charge accumulated in the capacitor of each pixel 101, and corresponds to a signal requesting reading of the pixel value of each pixel 101. The Req signal may be, for example, a simple binary signal or may include information regarding the address of each pixel 101 (for example, the X coordinate and the Y coordinate of each pixel 101).

FIG. 3 illustrates pixels P1 to P3 which are examples of the pixel 101. The pixel P1 is electrically connected to one signal line 105c and belongs to the group c. The pixel P2 is electrically connected to one signal line 105d and belongs to the group d. The pixel P3 is electrically connected to another signal line 105c and belongs to the group c. FIG. 3 further illustrates three Req signals output from the pixels P1 to P3. The Req signal output from the pixel P2 is input to the arbiter 103d. On the other hand, the Req signals output from the pixels P1 and P3 are input to the arbiter 103c and arbitrated by the arbiter 103c.

The signal lines 105a to 105d of the present embodiment are alternately arranged in the pixel array region 102. For example, each signal line 105c is adjacent to the signal lines 105b and 105d in the Y direction. In addition, each signal line 105d is adjacent to the signal lines 105c and 105a in the Y direction, or is adjacent to only the signal line 105c in the Y direction. As described above, the signal line 105 of a certain group is adjacent to the signal line 105 of another group in the Y direction, and is not adjacent to the signal line 105 of the same group in the Y direction.

Such an arrangement has an advantage that the number of times of arbitration of an event (Req signal) can be reduced, for example. In general, a phenomenon in which a plurality of events is simultaneously ignited is likely to occur in a plurality of pixels 101 arranged close to each other. Therefore, when the signal lines 105 of the same group are arranged close to each other, the pixels 101 of the same group are arranged close to each other, and a plurality of events is likely to be simultaneously ignited in the plurality of pixels 101 of the same group. As a result, arbitration of these events is required. According to the present embodiment, by alternately arranging the signal lines 105a to 105d, the number of times of simultaneous ignition of a plurality of events in a plurality of pixels 101 of the same group can be reduced, and the number of times of arbitration of an event can be reduced.

### [Arbiter 103]

The arbiters 103a to 103d belong to the groups a to d, respectively, and arbitrate events ignited in the pixels 101 of the groups a to d. The arbiters 103a to 103d of the present embodiment are arranged in the −X direction of the pixel array region 102, and are arranged in parallel with each other with respect to the pixel array region 102. In FIG. 3, the pixel array region 102 and the arbiters 103a to 103d are separated from each other in the X direction. The arbiters 103a to 103d are examples of the first to N-th arbiters of the present disclosure (here, N=4).

For example, when receiving the Req signal output from a certain pixel 101 of the group a, the arbiter 103a outputs the Req signal of the pixel 101 to the latch unit 104a via the signal line 107a. The Req signal output from the arbiter 103a may be the same signal as or a different signal from the Req signal received by the arbiter 103a. In addition, in a case where a plurality of events is simultaneously ignited in a plurality of pixels 101 of the group a, the arbiter 103a arbitrates a plurality of Req signals output from these pixels 101. Specifically, in a case where the arbiter 103a first receives the Req signal from the first pixel 101 and then receives the Req signal from the second pixel 101, the Req signal of the first pixel 101 is output to the latch unit 104a, and then the Req signal of the second pixel 101 is output to the latch unit 104a. That is, the Req signal of the first pixel 101 is preferentially output to the latch unit 104a, and the Req signal of the second pixel 101 is output to the latch unit 104a after a waiting time. The similarity applies to the arbiters 103b to 103d.

### [Signal Line 107]

The signal lines 107a to 107d are arranged outside the pixel array region 102. The signal lines 107a to 107d belong to the groups a to d, respectively, and electrically connect the arbiters 103a to 103d and the latch units 104a to 104d. The Req signals output from the arbiters 103a to 103d are transferred to the latch units 104a to 104d via the signal lines 107a to 107d, respectively.

### [Read Line 106]

The read lines 106a to 106d are arranged over the inside and the outside of the pixel array region 102, and are electrically connected to the latch units 104a to 104d, respectively. In the pixel array region 102, the read lines 106a to 106d extend in the Y direction and are separated from each other in the X direction. The read lines 106a to 106d of the present embodiment are used to read a pixel value from each pixel 101.

The solid-state imaging device of the present embodiment includes 12 signal lines 105a to 105d for the pixels 101 for 12 rows and 48 read lines 106a to 106d for the pixels 101 for 12 columns. The number of the read lines 106a to 106d is 48 instead of 12 because the number of the groups a to d is 4. The solid-state imaging device of the present embodiment includes 12 read lines 106a, 12 read lines 106b, 12 read lines 106c, and 12 read lines 106d. FIG. 3 illustrates only 12 read lines 106a to 106d among the 48 read lines a to d, and omits illustration of the remaining 36 read lines 106a to 106d, in order to avoid excessive complexity of the drawing.

Each of the read lines 106a to 106d is arranged at a position overlapping any column in the pixel array region 102 in the Z direction, and is electrically connected to three pixels 101 in this column. For example, the read line 106a illustrated on the leftmost side of FIG. 3 overlaps the second column from the left side of FIG. 3, and is electrically connected to the first pixel 101 from the top in this column as indicated by a black dot in FIG. 3. The read line 106a is further electrically connected to the fifth and ninth pixels 101 from the top in this column, but illustration of the black spot is omitted. The read line 106a may be arranged in the +Z direction of these pixels 101 or may be arranged in the −Z direction of these pixels 101. The similarity applies to the other read lines 106a to 106d.

The read lines 106a to 106d belong to the groups a to d, respectively. The pixels 101 belonging to the groups a to d are electrically connected to the latch units 104a to 104d via the read lines 106a to 106d, respectively. For example, the three read lines 106a illustrated in FIG. 3 and the nine pixels 101 electrically connected to these read lines 106a belong to the group a and are electrically connected to the latch unit 104a. The similarity applies to the other read lines 106a to 106d and the pixels 101.

Note that the first and second read lines 106a from the right in FIG. 3 are illustrated to be shorter than the third read line 106a from the right in FIG. 3 in order to avoid excessive complexity of the drawing, but actually have the same length as the third read line 106a from the right in FIG. 3. That is, all of the three read lines 106a extend to the uppermost row in FIG. 3. The similarity applies to the other read lines 106a to 106d. For example, all three read lines 106b illustrated in FIG. 3 extend to the second row from the top in FIG. 3.

Each column in the pixel array region 102 of the present embodiment overlaps the four read lines 106a to 106d in the Z direction due to the number of the groups a to d being four. Therefore, the width in the X direction of each pixel 101 of the present embodiment is set to be longer than the total value of the widths in the X direction of the four read lines 106a to 106d. As a result, the read lines 106a to 106d can be arranged at positions overlapping the pixels 101 for one column.

### [Latch Unit 104]

The latch units 104a to 104d belong to the groups a to d, respectively, and read pixel values from the pixels 101 of the groups a to d. The latch units 104a to 104d of the present embodiment are arranged in the −Y direction of the pixel array region 102, and are arranged in series with the arbiters 103a to 103d with respect to the pixel array region 102. Similarly to the arbiters 103a to 103d arranged in order in the −Y direction, the latch units 104a to 104d are also arranged in order in the −Y direction. In FIG. 3, the pixel array region 102 and the latch units 104a to 104d are separated from each other in the Y direction. The latch units 104a to 104d are examples of the first to N-th latch units of the present disclosure (here, N=4).

For example, when receiving the Req signal of a certain pixel 101 in the group a from the arbiter 103a, the latch unit 104a outputs an Ack (acknowledge) signal of the pixel 101 to the arbiter 103a via the signal line 107a. The Ack signal output from the latch unit 104a is a signal that approves resetting of the charge accumulated in the capacitor of the pixel 101, and corresponds to a signal that approves reading of the pixel value of the pixel 101. The Ack signal may be, for example, a simple binary signal or may include information regarding the address of the pixel 101 (for example, the X coordinate and the Y coordinate of the pixel 101). The similarity applies to the latch units 104b to 104d.

In this case, when receiving the Ack signal of a certain pixel 101 in the group a from the latch unit 104a, the arbiter 103a outputs the Ack signal of the pixel 101 to the pixel 101 via the signal line 105a. The Ack signal output from the arbiter 103a may be the same as or different from the Ack signal received by the arbiter 103a. When the pixel 101 receives the Ack signal, the charge accumulated in the capacitor of the pixel 101 is reset. Furthermore, the pixel value of the pixel 101 is transferred to the latch unit 104a via the read line 106a and stored in the latch unit 104a. As described above, the latch unit 104a can read the pixel value from the pixel 101 corresponding to the Req signal by outputting the Ack signal for the Req signal. The similarity applies to the latch units 104b to 104d.

The pixel value output from the pixel 101 of the group a to the latch unit 104a is, for example, a change amount of luminance when an event is ignited in the pixel 101. When the on-event is ignited, the change amount of the luminance becomes a positive value, and when the off-event is ignited, the change amount of the luminance becomes a negative value. Instead, the pixel value output to the latch unit 104a may be the luminance itself when the event is ignited. For example, the latch unit 104a outputs the X coordinate, the Y coordinate, the pixel value of the pixel 101, and a time stamp to be described later to the outside of the solid-state imaging device as information regarding each event. The similarity applies to the latch units 104b to 104d.

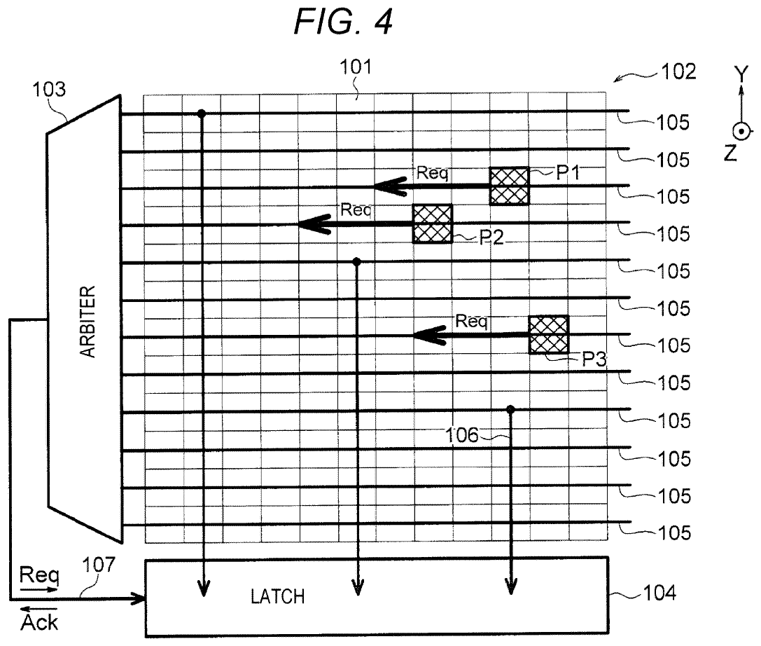

FIG. 4 is a block diagram illustrating a configuration of a solid-state imaging device of a comparative example of the first embodiment.

The solid-state imaging device of the present comparative example includes the pixel array region 102 including the plurality of pixels 101, the arbiter 103, the latch unit 104, the plurality of signal lines 105, the plurality of read lines 106, and the signal line 107. While the solid-state imaging device of the first embodiment has a configuration including the pixels 101 of the four groups a to d, the solid-state imaging device of the present comparative example has a configuration including the pixels 101 of only one group.

The 144 pixels 101 in the pixel array region 102 of the present comparative example belong to one group. Therefore, when an event is ignited at the same time in the plurality of pixels 101 in the pixel array region 102, arbitration of the event always occurs. Therefore, it is difficult to quickly process the event.

On the other hand, each pixel 101 in the pixel array region 102 of the first embodiment belongs to any of the four groups a to d. Therefore, even if an event is ignited simultaneously in a plurality of pixels 101 in the pixel array region 102, arbitration of the event does not occur as long as these pixels 101 belong to another group. As described above, according to the present embodiment, the pixels 101 in the pixel array region 102 are divided into a plurality of groups, and the arbiter 103 and the latch unit 104 are prepared for each group, whereby an event can be quickly processed. For example, by reducing the number of times of arbitration of an event, it is possible to quickly process the event.

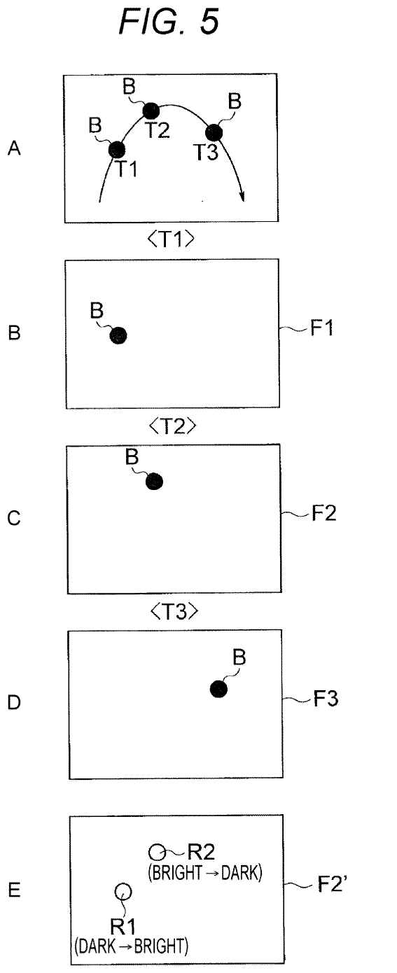

FIG. 5 is a diagram for explaining the operation of the solid-state imaging device of the first embodiment.

A of FIG. 5 illustrates a trajectory on which a black ball B moves in the space. A of FIG. 5 further illustrates the position of the ball B at times T1, T2, and T3.

B, C, and D of FIG. 5 illustrate examples of frames (images) F1, F2, and F3 obtained by photographing the ball B at times T1, T2, and T3 by the image sensor, respectively. Since the frame F1 is photographed at time T1, the position of the ball B illustrated in B of FIG. 5 is the position of the ball B at time T1 in A of FIG. 5. The similarity applies to the frame F2 and the frame F3.

E of FIG. 5 illustrates an example of a frame F2′ obtained by photographing the ball B at time T2 by the solid-state imaging device (EVS) of the present embodiment. A region R1 indicates a place where the ball B existed at time T1, and a region R2 indicates a place where the ball B reached at time T2. The region R1 is represented by, for example, “white” on the frame F2′ because the ball B has changed from a “certain state” to an “absent state” and changed from a dark state to a bright state. On the other hand, the region R2 is represented by, for example, “black” on the frame F2′ since the ball B has changed from an “absent state” to a “certain state” and changed from a bright state to a dark state. The other regions are represented by, for example, “grey” on the frame F2′.

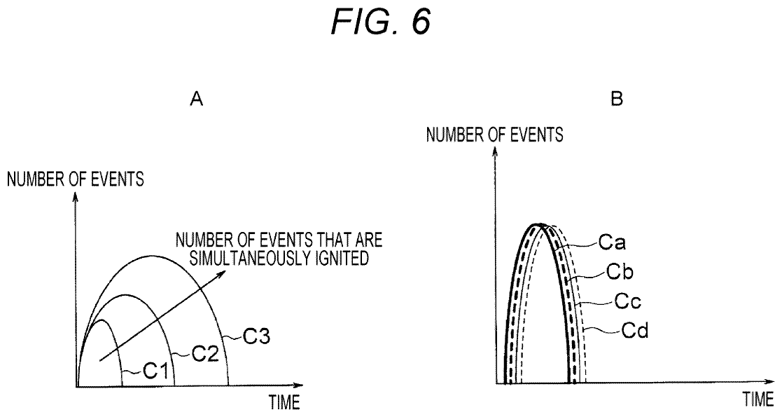

FIG. 6 is a graph for comparing the operation of the solid-state imaging device of the first embodiment with the operation of the solid-state imaging device of the comparative example of the first embodiment.

A of FIG. 6 illustrates a relationship between an error and the number of events for a large number of events ignited in the solid-state imaging device of the comparative example (FIG. 4). The horizontal axis indicates the time at which the time stamp is given to the event in a case where the time at which the event occurs is 0. Therefore, this time indicates an error between the timing at which the event occurs and the timing at which the time stamp is given to the event. As will be described later, the time stamp is given, for example, in the latch unit 104 after occurrence of an event. The vertical axis indicates the number of events corresponding to each time.

A of FIG. 6 illustrates that the relationship between the error and the number of events changes from a curve C1 to a curve C2 and changes from the curve C2 to a curve C3 when the number of events that ignite simultaneously increases. In the comparative example, since all the pixels 101 belong to the same group, when the number of events that are ignited at the same time increases, a large number of arbitration occurs, so that the number of events with large errors increases. Furthermore, the maximum value of the error also increases, and the processing delay increases.

B of FIG. 6 illustrates a relationship between an error and the number of events for a large number of events ignited in the solid-state imaging device of the first embodiment (FIG. 3). Curves Ca to Cd indicate the relationship between the error and the number of events for the pixels 101 of the groups a to d, respectively.

The pixels 101 of the present embodiment are divided into four groups a to d. Therefore, even if the number of events that are ignited at the same time increases, the number of events with a large error in the present embodiment does not increase rapidly as the number in the comparative example. Therefore, according to the present embodiment, it is possible to suppress the problem in the comparative example.

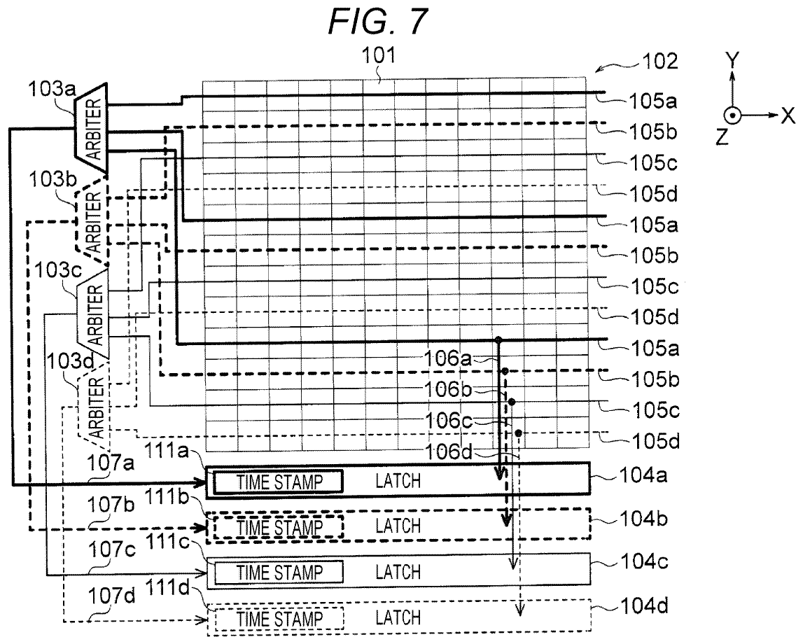

FIG. 7 is a block diagram illustrating a first configuration example of the solid-state imaging device of the first embodiment.

The solid-state imaging device illustrated in FIG. 7 includes a plurality of time stamp units 111a to 111d in addition to the components illustrated in FIG. 3. The time stamp units 111a to 111d are arranged in the latch units 104a to 104d, respectively. The time stamp units 111a to 111d are examples of first to N-th time stamp units (here, N=4). Each of the time stamp units 111a to 111d is also appropriately referred to as “time stamp unit 111”.

The time stamp unit 111a gives a time stamp to each event ignited in the pixel 101 belonging to the group a. For example, when the latch unit 104a receives a Req signal of a certain pixel 101 belonging to the group a from the arbiter 103a, the time stamp unit 111a gives a time stamp to an event corresponding to the Req signal using the Req signal as a trigger. This time stamp is stored in the time stamp unit 111a. Thereafter, the latch unit 104a outputs the X coordinate, the Y coordinate, and the pixel value of the pixel 101 and the time stamp given to the event to the outside of the solid-state imaging device as the information regarding the event. The similarity applies to the time stamp units 111b to 111d.

As described above, the solid-state imaging device illustrated in FIG. 7 includes the plurality of time stamp units 111a to 111d, and each of the time stamp units 111a to 111d gives a time stamp to an event ignited in the pixels 101 belonging to the groups a to d. In this case, if the operations of the time stamp units 111a to 111d are not synchronized, there is a possibility that time stamp units given by different time stamp units 111 cannot be compared with each other. Therefore, it is desirable that the time stamp units 111a to 111d operate on the basis of a common clock signal. The time stamp indicates, for example, the time at which the time stamp is given to the event.

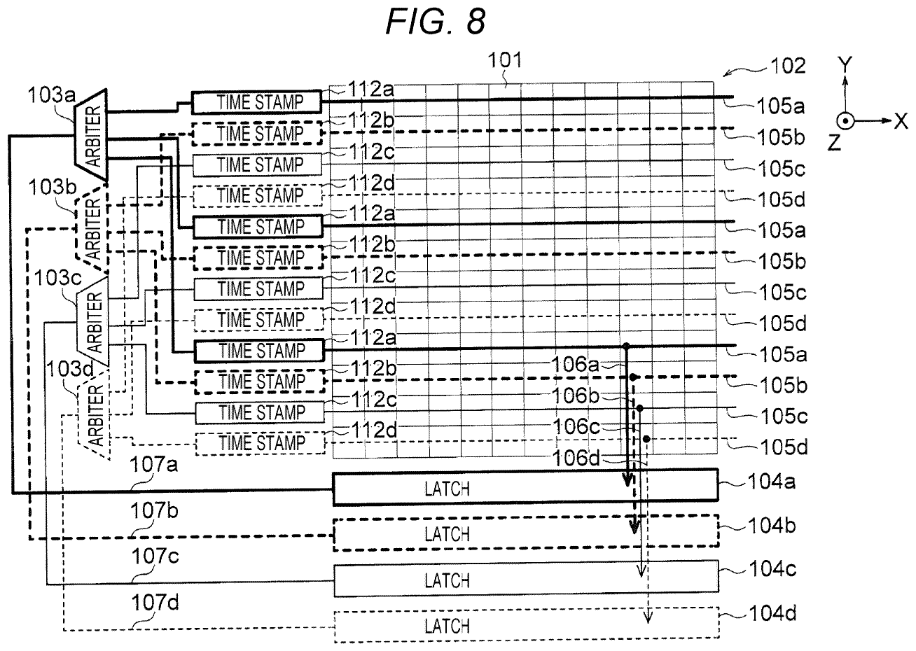

FIG. 8 is a block diagram illustrating a second configuration example of the solid-state imaging device of the first embodiment.

The solid-state imaging device illustrated in FIG. 8 includes a plurality of time stamp units 112a to 112d in addition to the components illustrated in FIG. 3. The time stamp units 112a to 112d are arranged between the pixel array region 102 and the arbiters 103a to 103d, respectively. Since the time stamp units 112a to 112d are arranged on the signal lines 105a to 105d, the solid-state imaging device illustrated in FIG. 8 includes 12 time stamp units 112a to 112d. The time stamp units 112a to 112d are examples of first to N-th time stamp units (here, N=4). Each of the time stamp units 112a to 112d is also appropriately referred to as “time stamp unit 112”.

Each time stamp unit 112a gives a time stamp to each event ignited in the pixel 101 electrically connected to the same signal line 105a as each time stamp unit 112a. For example, when the time stamp unit 112a receives a Req signal output from a certain pixel 101 belonging to the group a to the arbiter 103a, the time stamp unit 112a gives a time stamp to an event corresponding to the Req signal using the Req signal as a trigger. This time stamp is stored in the time stamp unit 112a. Thereafter, the latch unit 104a outputs the X coordinate, the Y coordinate, and the pixel value of the pixel 101 and the time stamp given to the event to the outside of the solid-state imaging device as the information regarding the event. In this case, when receiving the Ack signal corresponding to the event from the latch unit 104a, the arbiter 103a reads the time stamp of the event from one of the time stamp units 112a using the Ack signal as a trigger, and transmits the read time stamp to the latch unit 104a. The latch unit 104a outputs the time stamp to the outside of the solid-state imaging device. The similarity applies to the time stamp units 112b to 112d.

As described above, the solid-state imaging device illustrated in FIG. 8 includes the plurality of time stamp units 112a to 112d, and each of the time stamp units 112a to 112d gives a time stamp to an event ignited in the pixels 101 belonging to the groups a to d. In this case, if the operations of the time stamp units 112a to 112d are not synchronized, there is a possibility that time stamp units given by different time stamp units 112 cannot be compared with each other. Therefore, similarly to the time stamp units 111a to 111d, it is desirable that the time stamp units 112a to 112d operate on the basis of a common clock signal.

The time stamp units 112a to 112d illustrated in FIG. 8 are arranged on a step closer to the pixel array region 102 than the time stamp units 111a to 111d illustrated in FIG. 7. Therefore, according to the configuration illustrated in FIG. 8, it is possible to give a time stamp close to a true value to each event as compared with the configuration illustrated in FIG. 7.

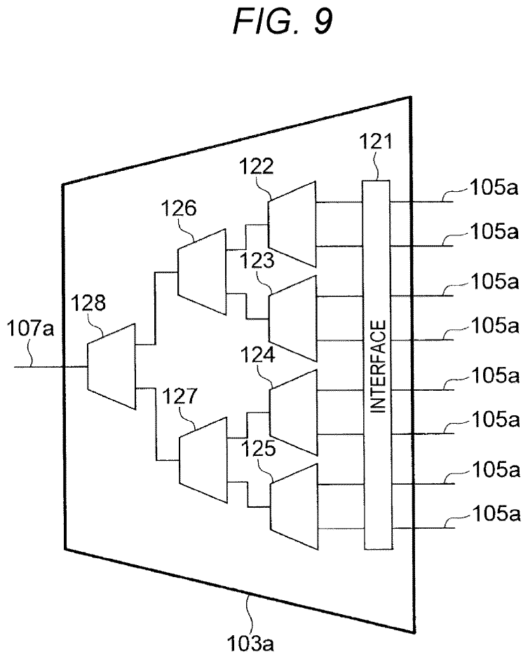

FIG. 9 is a circuit diagram illustrating a configuration example of the arbiter 103a of the first embodiment.

The arbiter 103a illustrated in FIG. 9 illustrates an interface 121 for eight signal lines 105a and seven arbiter circuits 122 to 128 constituting a tournament at a subsequent stage of the interface 121.

Each of the arbiter circuits 122 to 125 is electrically connected to two signal lines 105a, and arbitrates Req signals from these signal lines 105a. The arbiter circuit 126 arbitrates the Req signal output as a result of the arbitration from the arbiter circuit 122 and the Req signal output as a result of the arbitration from the arbiter circuit 123. The arbiter circuit 127 arbitrates the Req signal output as a result of the arbitration from the arbiter circuit 124 and the Req signal output as a result of the arbitration from the arbiter circuit 125. The arbiter circuit 128 arbitrates the Req signal output as a result of the arbitration from the arbiter circuit 126 and the Req signal output as a result of the arbitration from the arbiter circuit 127. The arbiter 103a outputs the Req signal output as a result of the arbitration from the arbiter circuit 128 to the signal line 107a.

Note that each of the arbiters 103b to 103d can be configured similarly to the arbiter 103a illustrated in FIG. 9.

### (3) Time Stamp Circuit of First Embodiment

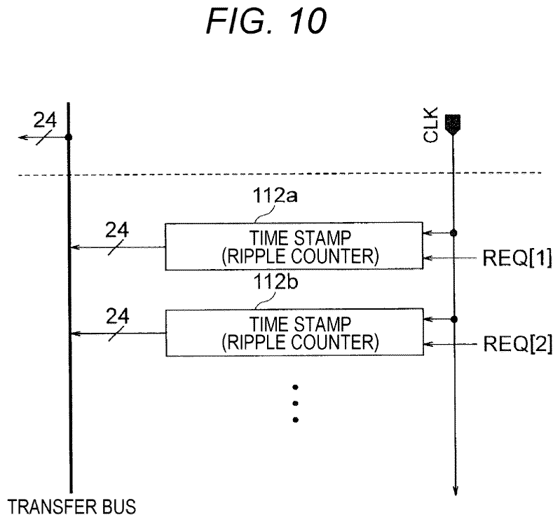

FIG. 10 is a circuit diagram illustrating a first configuration example of the time stamp circuit of the first embodiment.

FIG. 10 illustrates 2 time stamp units 112a and 112b among the above-described 12 time stamp units 112a to 112d (FIG. 8), and illustration of the other 10 time stamp units 112a to 112d is omitted. In FIG. 10, each time stamp unit 112 includes a ripple counter. Each ripple counter receives a Req signal from the corresponding signal line 105, and further receives a clock signal (CLK) common to all ripple counters.

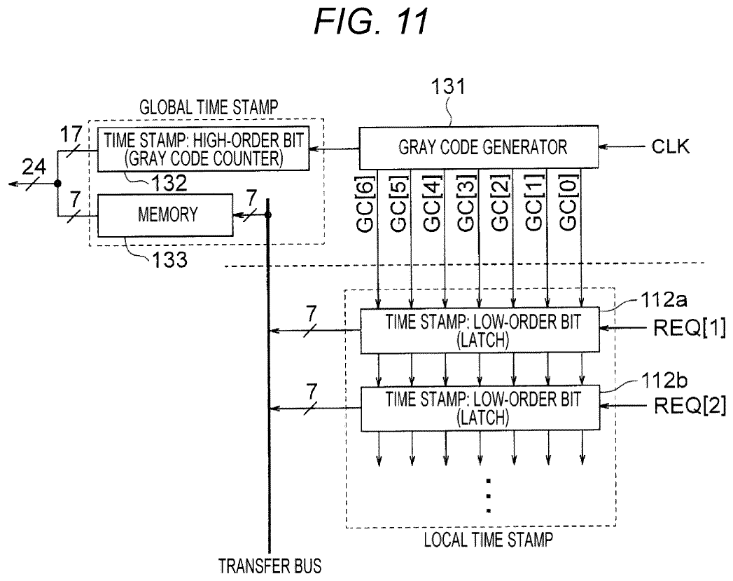

FIG. 11 is a circuit diagram illustrating a second configuration example of the time stamp circuit of the first embodiment.

FIG. 11 also illustrates 2 time stamp units 112a and 112b among the above-described 12 time stamp units 112a to 112d (FIG. 8), and illustration of the other 10 time stamp units 112a to 112d is omitted. In FIG. 11, each time stamp unit 112 receives the Req signal from the corresponding signal line 105.

FIG. 11 further illustrates a gray code generator 131, a gray code counter 132, and a memory 133 included in the solid-state imaging device of the present embodiment. In FIG. 11, the high-order bit of each time stamp is given by a global time stamp unit, and the low-order bit of each time stamp is assigned by a local time stamp unit. The operations of the global time stamp unit and the local time stamp unit are controlled by the gray code generator 131 to which a clock signal (CLK) is input.

The global time stamp unit generates time stamp units (high-order bits) for all the pixels 101. The global time stamp unit includes the gray code counter 132 corresponding to a time stamp unit of a high-order bit and the time stamp memory 133. On the other hand, the local time stamp unit generates a time stamp (low-order bit) by the time stamp units 112a to 112d corresponding to the groups a to d.

As described above, the pixels 101 of the present embodiment are divided into a plurality of groups, and the arbiter 103, the latch unit 104, the time stamp 111 (or 112), and the like are prepared for each group. Therefore, according to the present embodiment, it is possible to quickly process an event. For example, by reducing the number of times of arbitration of an event, it is possible to quickly process the event.

### (Second to Fourth Embodiments)

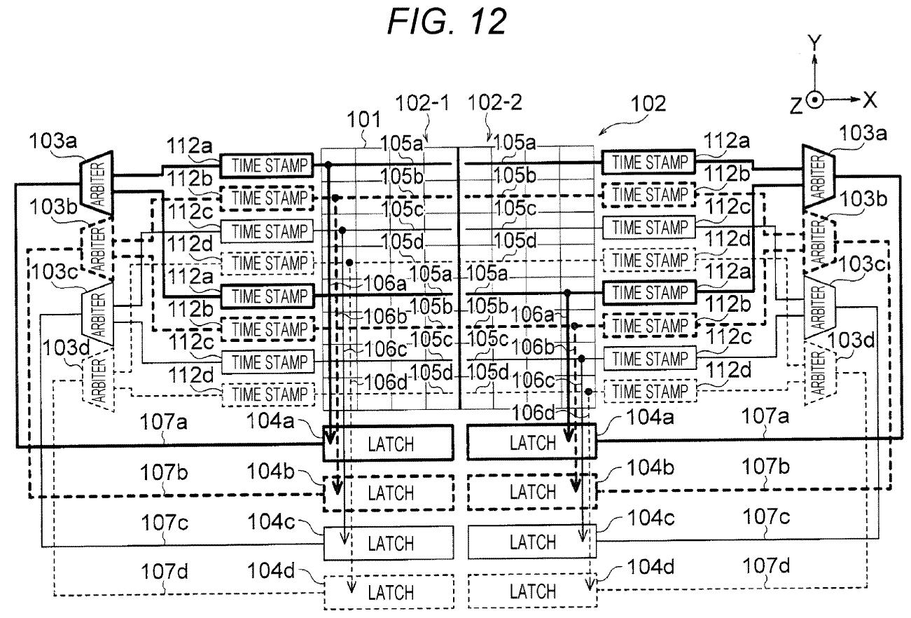

FIG. 12 is a block diagram illustrating a configuration of a solid-state imaging device according to a second embodiment.

The solid-state imaging device of the present embodiment has a configuration in which the pixel array region 102 of the solid-state imaging device of the first embodiment is divided into two partial regions 102-1 and 102-2. The partial regions 102-1 and 102-2 of the present embodiment are separated from each other in the X direction. Such division is called left-right division. The partial regions 102-1 and 102-2 of the present embodiment are examples of first and second regions of the present disclosure.

The configuration of each of the partial regions 102-1 and 102-2 of the present embodiment is similar to the configuration of the pixel array region 102 of the first embodiment. The solid-state imaging device of the present embodiment includes, for the partial region 102-1, four arbiters 103a to 103d, four latch units 104a to 104d, a plurality of signal lines 105a to 105d, a plurality of read lines 106a to 106d, a plurality of signal lines 107a to 107d, and a plurality of time stamp units 112a to 112d (may be 111a to 111d). The similarity applies to the partial region 102-2. However, the arbiters 103a to 103d of the partial region 102-1 are arranged in the −X direction of the partial region 102-1, and the arbiters 103a to 103d of the partial region 102-2 are arranged in the +X direction of the partial region 102-1.

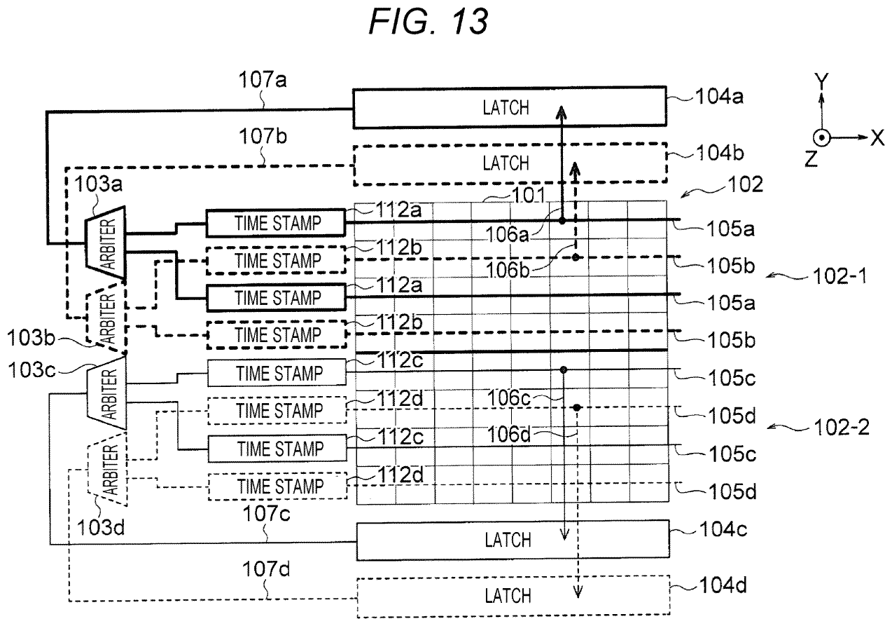

FIG. 13 is a block diagram illustrating a configuration of a solid-state imaging device of a third embodiment.

The solid-state imaging device of the present embodiment has a configuration in which the pixel array region 102 of the solid-state imaging device of the first embodiment is divided into two partial regions 102-1 and 102-2. The partial regions 102-1 and 102-2 of the present embodiment are separated from each other in the Y direction. Such division is called vertical division. The partial regions 102-1 and 102-2 of the present embodiment are examples of third and fourth regions of the present disclosure.

The configuration of each of the partial regions 102-1 and 102-2 of the present embodiment is similar to the configuration of the pixel array region 102 of the first embodiment. The solid-state imaging device of the present embodiment includes, for the partial region 102-1, two arbiters 103a to 103b, two latch units 104a to 104b, a plurality of signal lines 105a to 105b, a plurality of read lines 106a to 106b, a plurality of signal lines 107a to 107b, and a plurality of time stamp units 112a to 112b (may be 111a to 111b). The similarity applies to the partial region 102-2. However, the partial region 102-2 includes two arbiters 103c to 103d and the like instead of the two arbiters 103a to 103b and the like. Further, the latch units 104a to 104b of the partial region 102-1 are arranged in the +Y direction of the partial region 102-1, and the latch units 104c to 104d of the partial region 102-2 are arranged in the −Y direction of the partial region 102-1.

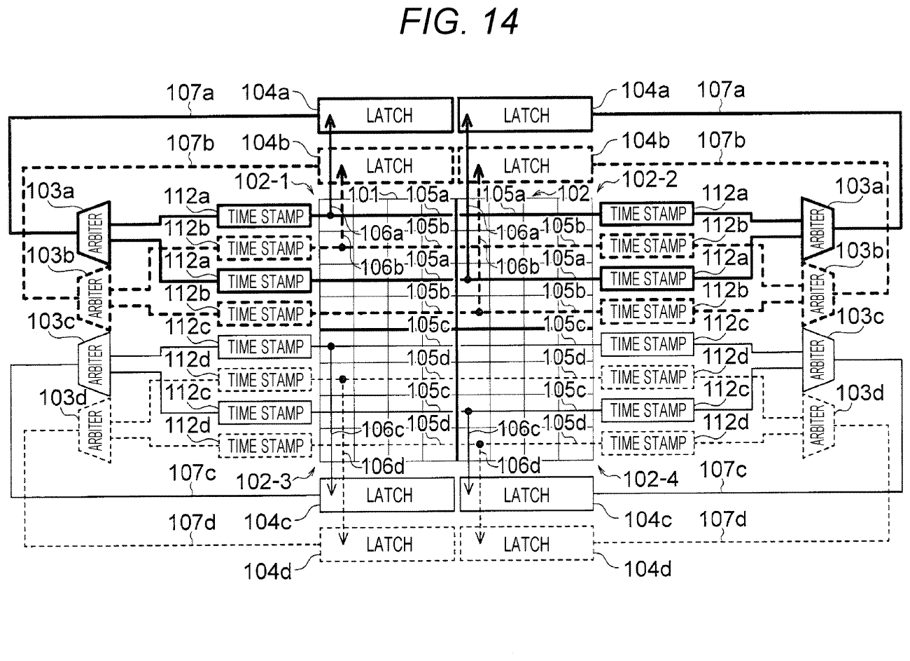

FIG. 14 is a block diagram illustrating a configuration of a solid-state imaging device of a fourth embodiment.

The solid-state imaging device of the present embodiment has a configuration in which the pixel array region 102 of the solid-state imaging device of the first embodiment is divided into four partial regions 102-1 to 102-4. The partial regions 102-1 to 102-4 of the present embodiment are separated from each other in the X direction and the Y direction. Two of the partial regions 102-1 to 102-4 of the present embodiment are examples of the first and second regions of the present disclosure or examples of the third and fourth regions of the present disclosure.

The partial regions 102-1 to 102-4 of the present embodiment have a configuration in which the configurations of the partial regions 102-1 to 102-2 of the second embodiment and the configurations of the partial regions 102-1 to 102-2 of the third embodiment are combined. Therefore, the solid-state imaging device of the present embodiment includes, for the partial region 102-1, two arbiters 103a to 103b, two latch units 104a to 104b, a plurality of signal lines 105a to 105b, a plurality of read lines 106a to 106b, a plurality of signal lines 107a to 107b, and a plurality of time stamp units 112a to 112b (may be 111a to 111b). The similarity applies to the partial regions 102-2 to 102-4. Detailed differences between the partial region 102-1 and other partial regions are similar to the contents described in the second and third embodiments.

According to the second to fourth embodiments, similarly to the first embodiment, it is possible to quickly process an event. The solid-state imaging devices of the second to fourth embodiments may include the time stamp circuit described with reference to FIG. 10 or 11 and the arbiter 103 described with reference to FIG. 12.

Note that the solid-state imaging devices of the first to fourth embodiments are provided and used in the vehicle 1, but may be used in other modes. For example, the solid-state imaging devices of these embodiments may be provided in an optical apparatus such as a camera and used, or may be provided in an information processing apparatus such as a personal computer (PC) or a smartphone and used.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A solid-state imaging device including:
a pixel array region including a plurality of pixels for detecting an event, each of the plurality of pixels belonging to any one of first to N-th (N is an integer of 2 or more) groups;
first to N-th arbiters respectively provided for the first to N-th groups of pixels, in which a K-th (K is an integer satisfying 1≤K≤N) arbiter receives a plurality of request signals output from a plurality of pixels of a K-th group and outputs a request signal corresponding to any one of the plurality of pixels of the K-th group; and
first to N-th latch units respectively provided for the first to N-th groups of pixels, in which a K-th latch unit reads a pixel value from a pixel corresponding to the request signal output from the K-th arbiter.
   (2)

The solid-state imaging device according to (1), in which the plurality of pixels in the pixel array region is arranged in a two-dimensional array along a first direction and a second direction.

(3)

The solid-state imaging device according to (2), in which
the pixel array region includes a plurality of signal lines extending in the first direction and separated from each other in the second direction,
each of the plurality of signal lines belongs to any one of the first to N-th groups, and
the first to N-th group signal lines respectively transfer request signals output from the first to N-th group pixels to the first to N-th arbiters.
   (4)

The solid-state imaging device according to (3), in which
each of the first to N-th groups includes two or more signal lines, and
each signal line of the K-th group is adjacent to a signal line other than the K-th group in the second direction.
   (5)

The solid-state imaging device according to (2), in which
the pixel array region includes a plurality of read lines extending in the second direction and separated from each other in the first direction,
each of the plurality of read lines belongs to any one of the first to N-th groups, and
the first to N-th group read lines respectively transfer pixel values output from the first to N-th group pixels to the first to N-th latch units.
   (6)

The solid-state imaging device according to (2), in which the first to N-th arbiters are arranged in the first direction of the pixel array region.

(7)

The solid-state imaging device according to (1), in which the first to N-th arbiters are arranged in parallel with each other with respect to the pixel array region.

(8)

The solid-state imaging device according to (2), in which the first to N-th latch units are arranged in the second direction of the pixel array region.

(9)

The solid-state imaging device according to (1), in which the first to N-th latch units are respectively arranged in series with the first to N-th arbiters with respect to the pixel array region.

(10)

The solid-state imaging device according to (1), in which the K-th latch unit reads the pixel value from a pixel corresponding to the request signal output from the K-th arbiter by outputting an acknowledge signal for the request signal output from the K-th arbiter.

(11)

The solid-state imaging device according to (1), further including first to N-th time stamp units that respectively give time stamps to events detected by the first to N-th group pixels.

(12)

The solid-state imaging device according to (11), in which the first to N-th time stamp units operate on the basis of a common clock signal.

(13)

The solid-state imaging device according to (11), in which the first to N-th time stamp units are respectively arranged in the first to N-th latch units.

(14)

The solid-state imaging device according to (11), in which the first to N-th time stamp units are respectively arranged between the pixel array region and the first to N-th arbiters.

(15)

The solid-state imaging device according to (11), in which the first to N-th time stamp units respectively give the time stamps with request signals output from the first to N-th group pixels as a trigger.

(16)

The solid-state imaging device according to (15), in which the first to N-th arbiters respectively read the time stamps from the first to N-th time stamp units by using acknowledge signals output from the first to N-th latch units as a trigger.

(17)

The solid-state imaging device according to (1), in which
the pixel array region includes a first region and a second region,
the first to N-th arbiters include first to N-th arbiters for the first region and first to N-th arbiters for the second region, and
the first to N-th latch units include first to N-th latch units for the second region and first to N-th latch units for the second region.
   (18)

The solid-state imaging device according to (17), in which
the first to N-th arbiters are separated from the pixel array region in a first direction,
the first to N-th latch units are separated from the pixel array region in a second direction, and
the first region and the second region are separated from each other in the first direction.
   (19)

The solid-state imaging device according to (1), in which
the pixel array region includes a third region and a fourth region,
a part of the first to N-th latch units is arranged in a vicinity of the third region, and
another part of the first to N-th latch units is arranged in a vicinity of the fourth region.
   (20)

The solid-state imaging device according to (19), in which
the first to N-th arbiters are separated from the pixel array region in a first direction,
the first to N-th latch units are separated from the pixel array region in a second direction, and
the third region and the fourth region are separated from each other in the second direction.

### REFERENCE SIGNS LIST

1 Vehicle
11 Vehicle control system
21 Vehicle control ECU
22 Communication unit
23 Map information accumulation unit
24 Position information acquisition unit
25 External recognition sensor
26 In-vehicle sensor
27 Vehicle sensor
31 Storage unit
32 Travel assistance/automated driving control unit
33 DMS
34 HMI
35 Vehicle control unit
41 Communication network
51 Camera
52 Radar
53 LiDAR
54 Ultrasonic sensor
61 Analysis unit
62 Action planning unit
63 Operation control unit
71 Self-position estimation unit
72 Sensor fusion unit
73 Recognition unit
81 Steering control unit
82 Brake control unit
83 Drive control unit
84 Body system control unit
85 Light control unit
86 Horn control unit
101 Pixel
102 Pixel array region
102-1 to 102-4 Partial region
103, 103a to 103d Arbiter
104, 104a to 104d Latch unit
105, 105a to 105d Signal line
106, 106a to 106d Read line
107, 107a to 107d Signal line
111a to 111d Time stamp unit
112a to 112d Time stamp unit
121 Interface
122 Arbiter circuit
123 Arbiter circuit
124 Arbiter circuit
125 Arbiter circuit
126 Arbiter circuit
127 Arbiter circuit
128 Arbiter circuit
131 Gray code generator
132 Gray code counter
133 Memory

1. A solid-state imaging device comprising:
a pixel array region including a plurality of pixels for detecting an event, each of the plurality of pixels belonging to any one of first to N-th (N is an integer of 2 or more) groups;
first to N-th arbiters respectively provided for the first to N-th groups of pixels, in which a K-th (K is an integer satisfying 1≤K≤N) arbiter receives a plurality of request signals output from a plurality of pixels of a K-th group and outputs a request signal corresponding to any one of the plurality of pixels of the K-th group; and
first to N-th latch units respectively provided for the first to N-th groups of pixels, in which a K-th latch unit reads a pixel value from a pixel corresponding to the request signal output from the K-th arbiter.

2. The solid-state imaging device according to claim 1, wherein the plurality of pixels in the pixel array region is arranged in a two-dimensional array along a first direction and a second direction.

3. The solid-state imaging device according to claim 2, wherein
the pixel array region includes a plurality of signal lines extending in the first direction and separated from each other in the second direction,
each of the plurality of signal lines belongs to any one of the first to N-th groups, and
the first to N-th group signal lines respectively transfer request signals output from the first to N-th group pixels to the first to N-th arbiters.

4. The solid-state imaging device according to claim 3, wherein
each of the first to N-th groups includes two or more signal lines, and
each signal line of the K-th group is adjacent to a signal line other than the K-th group in the second direction.

5. The solid-state imaging device according to claim 2, wherein
the pixel array region includes a plurality of read lines extending in the second direction and separated from each other in the first direction,
each of the plurality of read lines belongs to any one of the first to N-th groups, and
the first to N-th group read lines respectively transfer pixel values output from the first to N-th group pixels to the first to N-th latch units.

6. The solid-state imaging device according to claim 2, wherein the first to N-th arbiters are arranged in the first direction of the pixel array region.

7. The solid-state imaging device according to claim 1, wherein the first to N-th arbiters are arranged in parallel with each other with respect to the pixel array region.

8. The solid-state imaging device according to claim 2, wherein the first to N-th latch units are arranged in the second direction of the pixel array region.

9. The solid-state imaging device according to claim 1, wherein the first to N-th latch units are respectively arranged in series with the first to N-th arbiters with respect to the pixel array region.

10. The solid-state imaging device according to claim 1, wherein the K-th latch unit reads the pixel value from a pixel corresponding to the request signal output from the K-th arbiter by outputting an acknowledge signal for the request signal output from the K-th arbiter.

11. The solid-state imaging device according to claim 1, further comprising first to N-th time stamp units that respectively give time stamps to events detected by the first to N-th group pixels.

12. The solid-state imaging device according to claim 11, wherein the first to N-th time stamp units operate on a basis of a common clock signal.

13. The solid-state imaging device according to claim 11, wherein the first to N-th time stamp units are respectively arranged in the first to N-th latch units.

14. The solid-state imaging device according to claim 11, wherein the first to N-th time stamp units are respectively arranged between the pixel array region and the first to N-th arbiters.

15. The solid-state imaging device according to claim 11, wherein the first to N-th time stamp units respectively give the time stamps with request signals output from the first to N-th group pixels as a trigger.

16. The solid-state imaging device according to claim 15, wherein the first to N-th arbiters respectively read the time stamps from the first to N-th time stamp units by using acknowledge signals output from the first to N-th latch units as a trigger.

17. The solid-state imaging device according to claim 1, wherein
the pixel array region includes a first region and a second region,
the first to N-th arbiters include first to N-th arbiters for the first region and first to N-th arbiters for the second region, and
the first to N-th latch units include first to N-th latch units for the second region and first to N-th latch units for the second region.

18. The solid-state imaging device according to claim 17, wherein
the first to N-th arbiters are separated from the pixel array region in a first direction,
the first to N-th latch units are separated from the pixel array region in a second direction, and
the first region and the second region are separated from each other in the first direction.

19. The solid-state imaging device according to claim 1, wherein
the pixel array region includes a third region and a fourth region,
a part of the first to N-th latch units is arranged in a vicinity of the third region, and
another part of the first to N-th latch units is arranged in a vicinity of the fourth region.

20. The solid-state imaging device according to claim 19, wherein
the first to N-th arbiters are separated from the pixel array region in a first direction,
the first to N-th latch units are separated from the pixel array region in a second direction, and
the third region and the fourth region are separated from each other in the second direction.
